(19) United States
(12) Patent Application Publication
(10) Pub. No.: US 2007/0000444 A1
(43) Pub. Date: Jan. 4, 2007

(54) Vacuum evaporation apparatus and method of producing electro-optical device

(75) Inventor: Yuichi Shimizu, Hokuto-shi (JP)

Correspondence Address: ADVANTEDGE LAW GROUP, LLC, 1928 E. COBBLESTONE RD., SUITE 100, SPRINGVILLE, UT, 84663, US

(73) Assignee: Seiko Epson Corporation, Shinjuku-ku (JP)

(21) Appl. No.: 11/449,112

(22) Filed: Jun. 8, 2006

(30) Foreign Application Priority Data
Jul. 4, 2005 (JP) 2005-195463
Jan. 18, 2006 (JP) 2006-009610

(51) Int. Cl. C23C 16/00

(52) U.S. Cl. 118/720; 118/726; 118/730

(57) ABSTRACT

A vacuum evaporation apparatus includes a first vacuum tank holding an evaporation substance, a second vacuum tank in communication with the first vacuum tank, an electron beam irradiator in the first vacuum tank that evaporates the evaporation substance with an electron beam, a holder that holds a substrate in the second vacuum tank, a rotator that rotates the holder so that the held substrate is rotated in the second vacuum tank in a direction orthogonal to the flight direction of evaporated substance from the first vacuum tank, and a restrictor between the evaporation source and the substrate.

### BACKGROUND

1. Technical Field

The present invention relates to a technical field of a vacuum evaporation apparatus that can be suitably used for forming an inorganic alignment layer in an electro-optical device such as a liquid crystal device by oblique evaporation and a method of producing an electro-optical device using the same.

2. Related Art

In the above technical field, for example, JP-A-2004-332101 discloses a film deposition apparatus including a collimator. According to the film deposition apparatus disclosed in JP-A-2004-332101, in a vacuum tank or a vacuum chamber, the collimator is provided between a target and a substrate on which a film is deposited. The collimator controls particles moving from the target to the substrate so that the particles fly in a direction oblique to the surface of the substrate, the surface having the film thereon. Consequently, the apparatus can be reduced in size and maintenance of the apparatus can be performed more easily.

In the technical field, for example, JP-A-2003-202573 discloses a technique in which a metal oxide film is deposited by electron beam evaporation from a direction oblique to the surface of a substrate.

When an evaporation substance is uniformly deposited on a substrate, the optimum distance between an evaporation source and the substrate or a distance required therebetween depends on physical conditions of the evaporation source and physical conditions of the substrate. From a viewpoint of improving productivity, the evaporation source and the substrate are preferably large to a certain degree. Accordingly, the distance between the evaporation source and the substrate is large so that the deviation of the distribution of the evaporation substance can be cancelled out. Therefore, as in the known evaporation apparatus, even when the apparatus can be reduced in size by controlling the evaporation substance so as to move in a direction oblique to the substrate using the collimator or the like, it is difficult to change the macroscopic dimensions of the evaporation apparatus and to satisfactorily improve the ease of maintenance, which affects productivity of the evaporation apparatus. That is, the known evaporation apparatus has a technical problem in that it is difficult to satisfactorily improve productivity of the evaporation apparatus.

### SUMMARY

In particular, when an inorganic alignment layer having a predetermined pretilt angle is formed by oblique evaporation on a substrate such as an element substrate or a countersubstrate that constitutes an electro-optical device such as a liquid crystal device, according to film deposition using the known evaporation apparatus, practically, it is extremely difficult to uniformly form the inorganic alignment layer over the entire surface of the substrate when the entire vacuum tank is of a smaller size.

An advantage of some aspects of the invention is that it provides a vacuum evaporation apparatus that can improve productivity and a method of producing an electro-optical device using the same.

A vacuum evaporation apparatus according to a first aspect of the invention includes a first vacuum tank that defines a first space within which an evaporation source is placed and that can maintain a vacuum state of the first space, an electron beam irradiator that is provided in the first space and that irradiates an electron beam on the evaporation source to evaporate part of the evaporation source as an evaporated substance, a second vacuum tank that defines a second space being capable of communicating with the first space and within which a substrate is placed on which the evaporated substance is deposited as a deposited film and that can maintain a vacuum state of the second space in a state in which at least the second space communicates with the first space, a holder that holds the substrate so that at least part of the substrate faces at least part of the evaporation source in the second space, a rotator that rotates the holder so that the held substrate is rotated in the second space in a direction orthogonal to the flight direction of the evaporated substance made to fly from the first space, and a restrictor that is provided between the evaporation source and the substrate and that restricts the access of the evaporated substance on the substrate. In the vacuum evaporation apparatus, the restrictor restricts the access of the evaporated substance on the substrate so that the film properties of the deposited film become close to predetermined properties compared with the case where the access on the substrate is not restricted.

A vacuum evaporation apparatus according to a second aspect includes a first vacuum tank that defines a first space within which an evaporation source is placed and that can maintain a vacuum state of the first space, an electron beam irradiator that is provided in the first space and that irradiates an electron beam on the evaporation source to evaporate part of the evaporation source as an evaporated substance, a second vacuum tank that defines a second space being capable of communicating with the first space and within which a substrate is placed on which the evaporated substance is deposited as a deposited film and that can maintain a vacuum state of the second space in a state in which at least the second space communicates with the first space, a holder that holds the substrate so that at least part of the substrate faces at least part of the evaporation source in the second space, a rotator that rotates the holder so that the held substrate is rotated in the second space in a direction orthogonal to the flight direction of the evaporated substance made to fly from the first space, and a restrictor that is provided between the evaporation source and the substrate and that restricts the access of the evaporated substance on the substrate. In the vacuum evaporation apparatus, the restrictor includes a shielding portion covering at least a part of a communication surface between the second space and a third space, and an opening portion provided in a part of the shielding portion. In the vacuum evaporation apparatus, the surface of the opening portion adjacent to the communication surface has a shape gradually diverging from an axis defining the rotation center of the holder.

The term “first vacuum tank” according to the aspects denotes a concept including a box such as a chamber that defines a first space within which an evaporation source (also referred to as a target) is placed and that can maintain a vacuum state of the first space. The shape, the material, and the like of the first vacuum tank are not particularly limited as long as the concept is satisfied. However, in view of mechanical, physical, and chemical stabilities, preferred examples of the material constituting the first vacuum tank include metals, steels, glass, and ceramics.

The term “vacuum state” denotes a concept including a state of a space filled with a gas having a pressure lower than atmospheric pressure. Preferably, the term “vacuum state” represents a state of a space in which the pressure is reduced from atmospheric pressure to the extent that impurities such as oxygen and nitrogen contained in the air do not affect the quality of a film when the film is formed by depositing an evaporated substance on a substrate. The structure of an evacuation mechanism, an evacuation unit, or an evacuation system for forming the vacuum state is also not particularly limited as long as the vacuum state can be formed. For example, the vacuum state may be formed with a rotary pump, a mechanical booster pump, an oil-diffusion pump, or a turbomolecular pump. Alternatively, in view of the evacuation characteristics of these pumps, the vacuum state may be formed using these pumps as a preliminary evacuation system and a main evacuation system in combination. The phrase “maintain a vacuum state” denotes a concept including a state in which the degree of vacuum is constantly stable or the degree of vacuum can be considered to be constant as a result of canceling out the amount of gas evacuated by the evacuation system and the amount of leakage of a gas in the first vacuum tank.

The term “evaporation source” according to the aspects denotes a concept including substances that can be evaporated by heating with an electron beam. The material, the shape, and other physical properties of the evaporation source are not particularly limited as long as the concept is satisfied. For example, the evaporation source may be an inorganic material such as SiO or SiO₂. Alternatively, the evaporation source may be an inorganic material that can be used as a material of an inorganic alignment layer in an electro-optical device such as a liquid crystal device.

In addition to the evaporation source, an electron beam irradiator is disposed in the first space. Among a mechanism, a unit, or a system for evaporating part of the evaporation source as an evaporated substance by irradiating the evaporation source with an electron beam, the electron beam irradiator according to the aspects denotes a concept including at least a part of the mechanism, the unit, or the system disposed in the first space. For example, the electron beam irradiator constitutes a part of an electron gun unit. For example, the electron gun unit generally includes a filament, a control system, a power supply system, a cooling water system, and the like. Among these, the electron gun unit serving as the electron beam irradiator according to the aspects constitutes the part disposed in the first vacuum tank. Accordingly, all of the control system, the power supply system, the cooling water system, and the like need not be disposed in the first space. For example, a control unit, a power supply, a cooling water source, and the like may be disposed outside the first space. Part of the evaporation source evaporated by the electron beam irradiator reaches the second space defined in the second vacuum tank as the evaporated substance.

The term “second vacuum tank” according to the aspects denotes a concept including a box such as a chamber that defines the second space being capable of communicating with the first space and that can maintain a vacuum state of the second space in a state in which at least the second space communicates with the first space. The material, the shape, and the like of the second vacuum tank are not particularly limited like the first vacuum tank. The vacuum state in the second space may be realized with various evacuation systems in the first vacuum tank. The degree of vacuum represented by a physical numerical value in the first space is not necessarily the same as that in the second space. Alternatively, various evacuation systems that are the same as or different from those in the first vacuum tank may be connected to the second vacuum tank so that the second space is actively maintained in a vacuum state. In any case, in the second vacuum tank, the second space can be maintained in a vacuum state in a state in which the first space communicates with the second space.

A substrate on which the evaporated substance from the evaporation source is deposited as a deposited film is disposed in the second space. The number of the substrates disposed in the second space is not particularly limited as long as the evaporation operation according to the aspects is not impaired. Accordingly, the vacuum evaporation apparatus according to the aspects may be a single substrate-type vacuum evaporation apparatus in which a single substrate is disposed in the second space or a batch-type vacuum evaporation apparatus in which a plurality of substrates are disposed therein. When a plurality of substrates are disposed, the number of substrates that can be simultaneously processed increases, and thus the process is efficient and can greatly contribute to the improvement in productivity.

In the second space, the substrate is held by a holder so that at least part of the substrate faces at least part of the evaporation source. Herein, the term “face” means not only the case where the substrate faces the evaporation source in parallel, but also the case where the substrate faces the evaporation source obliquely at a predetermined angle relative to the flight direction (i.e., evaporation direction) of the evaporation source or the evaporated substance. The form of the “holder” according to the aspects is not particularly limited as long as the holder can hold the substrate so that at least part of the substrate faces at least part of the evaporation source.

In addition, the holder is rotated by the operation of a rotator so that the substrate is rotated in the second space in a direction orthogonal to the flight direction of the evaporated substance made to fly from the first space through, for example, a third space described below. By rotating the substrate, a uniform film such as an inorganic alignment layer can be formed over the entire area or a relatively wide range of the substrate.

In view of such an operation of the rotator, the phrase “at least part of the substrate faces” includes the case where the substrate held by the holder passes above a communication surface in the second space, the surface being adjacent to the first space, during at least a part of the rotation process.

The form of the rotator is not particularly limited as long as the rotator can rotate the holder as described above. For example, the rotator may be a unit, a mechanism, or a system that rotates the holder using an electric motor or the like as a power source. A part of the rotator may be disposed outside the second vacuum tank. For example, a part of a motive power system, a control system, or the like may be disposed outside the second vacuum tank. In this case, the motive power, the control signal, or the like for a component, a member, or the like that directly rotates the holder may be supplied via a slip ring or the like.

The substrate is finally rotated by the operation of the rotator in a direction orthogonal to the flight direction of the evaporated substance, that is, rotated around the rotator. Furthermore, the substrate may be rotated on its own axis by the rotator or another unit as long as the substrate is rotated around the rotator in that manner. That is, the substrate may be relatively freely transferred in the second space as long as the quality of the deposited film can become uniform.

Controlled variables, such as the rotational speed, that specify the rotational characteristics during the rotation of the holder by the rotator may be determined on the basis of, for example, experimentation, experience, or simulation in advance.

From the viewpoint that the second space serves as an evaporation chamber (or a film deposition chamber), a load-lock chamber for supplying the second space with substrates, a transfer chamber for discharging a substrate after evaporation (or film deposition) from the second space, and the like may be appropriately connected to the second vacuum tank. When such a load-lock chamber and a transfer chamber that relate to a preprocessing and a postprocessing, respectively, are connected to the second vacuum tank, a pretreatment such as prebaking and a posttreatment such as postbaking may be performed in the chambers.

In particular, when the productivity is improved in view of the film quality of the deposited film, the evaporated substance made to fly from the first space through the third space described below must be suitably deposited on the rotating substrate. For example, even although an unevenness of evaporation between the substrates can be cancelled out by rotating the substrates, an unevenness of evaporation may be generated within a substrate. Since such an unevenness of evaporation in a substrate decreases the yield, in this case, the productivity of the vacuum evaporation apparatus may be ultimately decreased. Consequently, in the vacuum evaporation apparatus according to the aspects of the invention, this problem is appropriately solved by an operation of a restrictor.

The restrictor according to the aspects is provided between the evaporation source and the substrate in the second vacuum tank or in the vicinity thereof. The restrictor restricts the access of the evaporated substance on the substrate so that the film properties of the deposited film formed on the substrate become close to predetermined properties compared with the case where the access of the evaporated substance on the substrate is not restricted at all.

Herein, the term “film properties” denotes a concept including the physical, mechanical, electrical, and chemical properties of the deposited film. Examples thereof include the film thickness, refractive index, and alignment direction of the evaporated substance. The term “predetermined properties” represents the indices of the film properties specified as the above concept. However, these indices need not be specifically provided with numerical values, that is, need not be quantitatively provided, but may be provided qualitatively. In addition, when the indices are numerically provided, the numerical values may be specified as an appropriate range. The phrase “become close to predetermined properties” denotes a concept including a phenomenon that the film properties of the deposited film become close to or gradually become close to predetermined properties to some degree compared with the case where no countermeasure is taken, that is, compared with the case where the access of the evaporated substance on the substrate is not restricted at all. The deposited film does not necessarily have the predetermined properties as long as the above concept is satisfied.

The restrictor may have any form as long as the access of the evaporated substance on the substrate is restricted. Preferably, the restrictor is a component that is provided between the evaporation source and the substrate and that physically restricts the access on the substrate, for example, a shielding plate, a shield, a deposition-preventing plate, or the like. However, the restrictor is not limited thereto. For example, the restrictor may have a form that mechanically, electrically, or chemically restricts the access of the evaporated substance on the substrate. The material, the shape, and the like of the restrictor may be determined on the basis of, for example, experimentation, experience, or simulation in advance so that the film properties of the deposited film become close to predetermined film properties.

Thus, according to the vacuum evaporation apparatus according to the aspects of the invention, by the operation of the restrictor, the evaporated substance can be deposited on the substrate so as to provide predetermined film properties. Consequently, the film quality of the deposited film can be improved, that is, productivity can be increased.

According to an embodiment of the vacuum evaporation apparatus according to the first aspect of the invention, the vacuum evaporation apparatus may further include a third vacuum tank that is provided between the first vacuum tank and the second vacuum tank so as to be removable from each of the first vacuum tank and the second vacuum tank, that defines a third space (i) capable of communicating with the first space and the second space and (ii) functioning as a space through which the evaporated substance is made to fly to the second space in a state in which the third vacuum tank is connected to the first vacuum tank and the second vacuum tank, and that can maintain a vacuum state of the third space in a state in which at least the third space communicates with the first space and the second space.

According to this embodiment, the third vacuum tank that is removable from each of the first vacuum tank and the second vacuum tank is provided between the first vacuum tank and the second vacuum tank. The third vacuum tank defines the third space. In a state in which the third vacuum tank is connected to the first vacuum tank and the second vacuum tank (that is, in a state in which the third vacuum tank is not removed from the other tanks), the third space serves as a space which can communicate with the first space and the second space and through which the evaporated substance from the evaporation source is made to fly to the second space. That is, the first space and the second space communicate with each other through the third space.

In the third vacuum tank, the third space can be maintained in a vacuum state when the third space communicates with the first space and the second space. The third vacuum tank according to the embodiment denotes a concept including a tubular component defining such a third space. The material and the shape of the third vacuum tank are not particularly limited as long as the above concept is satisfied. The vacuum state of the third space may be maintained by means of the evacuation system provided in the first vacuum tank and the additional evacuation system provided in the second vacuum tank. Alternatively, the vacuum state of the third space may be maintained by providing a separate evacuation system in the third vacuum tank.

The third vacuum tank may be connected directly or indirectly to the first vacuum tank and the second vacuum tank. Herein, the phrase “connected indirectly” means that the third vacuum tank is connected to another tank with, for example, a sealing component such as a flange, a gasket, or a coupler; a dummy chamber merely serving as a hollow space; or a preliminary evacuation chamber provided therebetween. Also, it means that the third vacuum tank is connected to another tank with a valve operating mechanism, such as a gate valve, provided therebetween. However, even when the third vacuum tank is connected indirectly to the first vacuum tank and the second vacuum tank with intermediate components such as a flange, the evaporated substance can fly from the first space to the second space. From this point of view, these intermediate components may also be considered as a type of the third vacuum tank. That is, the third vacuum tank is not necessarily a tubular component composed of a single component.

On the other hand, the third vacuum tank is removable from the first and second vacuum tanks (that is, a state in which the third vacuum tank is removed from the other tanks). From the viewpoint that the third vacuum tank is detached from the first vacuum tank and the second vacuum tank while the vacuum states of the first space and the second space are maintained, a component for maintaining the vacuum state is preferably provided between the third space and the first space and between the third space and the second space. In this case, for example, even when the third vacuum tank is detached from the first vacuum tank and the second vacuum tank in order to perform maintenance of the vacuum evaporation apparatus, the vacuum state of the first space and that of the second space are not degraded. As the internal volume of the vacuum evaporation apparatus increases, the time required for evacuation is inevitably increased. Therefore, when the vacuum state can be locally maintained as in this case, preferably, the time required for the maintenance of the vacuum evaporation apparatus can be reliably reduced, and thus productivity can be reliably increased.

A plate-shaped on-off valve referred to as a gate valve can be suitably used as a unit for switching the communicating state, i.e., communication or separation. In this case, the unit may further include a mechanism for opening and closing the gate valve. Such a mechanism may be accommodated in a flange or the like provided between the first vacuum tank and the third vacuum tank or between the second vacuum tank and the third vacuum tank.

As described above, the third vacuum tank is removable from the first and second vacuum tanks. Therefore, the maintenance can be separately performed. The ease of maintenance of the vacuum evaporation apparatus is improved, thus contributing to the improvement in productivity.

From the viewpoint that the third vacuum tank is removable from the first and second vacuum tanks, the third vacuum tank may be composed of a plurality of partial vacuum tanks which are removable from each other and whose lengths are different from each other or the same. Thereby, the distance between the evaporation source and the substrate can be easily optimized while a common main unit of the vacuum evaporation apparatus is used. This structure can contribute to the improvement in productivity in view of the optimization of the film quality. The material, the shape, and the like of these partial vacuum tanks may be different from each other as long as the partial vacuum tanks constitute the third vacuum tank as a whole. From the viewpoint that the third vacuum tank defines the third space serving as a flight space of the evaporated substance, these partial vacuum tanks must be hermetically connected to each other to the extent of maintaining the vacuum state. From this point of view, preferably, the partial vacuum tanks are composed of the same material and have the same macroscopic shape. However, in such a case, the distances through which the evaporated substance is made to fly (i.e., the length of the tube) may be different from each other.

According to another embodiment of the vacuum evaporation apparatus according to the first aspect of the invention, the holder preferably holds the substrate so that at least part of the substrate obliquely faces the evaporated substance made to fly from the first space.

According to this structure, for example, an inorganic alignment layer with a predetermined pretilt angle can be formed by oblique evaporation on a substrate such as an element substrate or a countersubstrate that constitutes an electro-optical device such as a liquid crystal device. That is, oblique evaporation can be suitably performed. In particular, a uniform inorganic alignment layer can be formed over the entire area or a relatively wide range of the substrate when the entire vacuum tank is of a smaller size.

According to another embodiment of the vacuum evaporation apparatus according to the first aspect of the invention, the film properties preferably include the thickness of the deposited film, and the restrictor preferably restricts the access of the evaporated substance on the substrate so that the thickness is within a predetermined range.

According to this embodiment, since the deposited film having a uniform thickness can be formed, a deposition process of high quality can be realized and productivity of the vacuum evaporation apparatus can be increased. Herein, the phrase “so that the thickness is within a predetermined range” represents the following concept: A film having a strictly uniform thickness is deposited over the entire area or a predetermined area of the surface of the substrate. In addition, the deposited film has a thickness in a range that is considered to be uniform in view of the required quality.

According to another embodiment of the vacuum evaporation apparatus according to the first aspect of the invention, the film properties preferably include the aligned state of the deposited film, and the restrictor preferably restricts the access of the evaporated substance on the substrate so that the aligned state becomes close to being uniform compared with the case where the access on the substrate is not restricted.

The term “aligned state” according to the embodiment denotes a concept including a state of alignment during deposition of the evaporated substance on the substrate. For example, the aligned state includes the alignment direction of the deposited film formed on the substrate.

For example, when an alignment film that can be suitably used in an electro-optical device such as a liquid crystal device is formed using the vacuum evaporation apparatus according to the first aspect of the invention, the film thickness is uniform but the alignment direction of the deposited film may not be uniform, thereby providing an undesirable alignment film in some cases. This embodiment is effective in that the restrictor restricts the access of the evaporated substance on the substrate so that the aligned state, which is considered as a concept including the alignment direction, becomes uniform.

In the embodiment including the third vacuum tank, the second vacuum tank may be provided so that the center of a communication surface between the second space and the third space does not intersect with an axis defining the rotation center of the holder.

According to this structure, when the center of the communication surface between the second space and the third space does not intersect with the axis defining the rotation center of the holder, the substrate passes over the communication surface during at least part of the period of the rotation process. In this case, when the second space is sufficiently larger than the communication part, in particular, the evaporated substance is dominantly deposited over the communication surface. Accordingly, the evaporation source can be efficiently used and a plurality of substrates can be relatively easily disposed in the second space. That is, productivity of the vacuum evaporation apparatus can be increased.

In the embodiment including the third vacuum tank, the restrictor may include a shielding portion covering at least a part of a communication surface between the second space and the third space, and an opening portion provided in a part of the shielding portion.

This structure can physically restrict the access of the evaporated substance on the substrate relatively easily. Herein, the term “shielding portion” denotes a concept including a unit that can cover at least a part of the communication surface between the second space and the third space. Examples thereof include components having a plate shape, a bulky shape, or another similar shape.

The opening portion is a space opening toward the second space and the third space in a part of the shielding portion, that is, a space in which a part of a surface of the shielding portion adjacent to the communication surface between the second space and the third space is opened. This opening portion can be considered as a “hole”. The term “surface adjacent to the communication surface” denotes a concept including a surface portion of the shielding portion covering the communication surface. Accordingly, the surface does not represent only a surface parallel to the communication surface in the strict sense, and may be a surface adjacent to the communication surface in the macroscopic sense. The evaporated substance can enter the second space mainly through this opening portion. The film properties of the deposited film mainly depend on the shape of the surface of the opening portion adjacent to the communication surface. The phrase “covering at least a part of the communication surface” does not mean only a state of physically adhering to or contacting the communication surface. It also includes a state in which the shielding portion is disposed above the communication surface with a clearance provided therebetween, the clearance substantially satisfying the concept of the shielding portion.

When the shielding portion has a small (i.e., thin) shape to the extent that the thickness of the shielding portion in the flight direction of the evaporated substance is negligible, as described above, the access of the evaporated substance on the substrate is two-dimensionally restricted mainly on the basis of the shape of the opening portion. In contrast, when the shielding portion has a significant thickness in the flight direction of the evaporated substance, the evaporated substance also collides with the inner wall of the shielding portion (i.e., the wall defining the opening portion) when passing through the opening portion, and thus the access of the evaporated substance on the substrate is three-dimensionally restricted. In this case, the film properties of the deposited film depend on the three-dimensional shape of the opening portion.

As described above, according to the restrictor including the shielding portion and the opening portion, the film properties of the deposited film can be matched with predetermined properties relatively easily and closely. The shapes of the shielding portion and the opening portion may be determined in advance on the basis of experimentation, experience, simulation, or the like so that the deposited film has predetermined properties.

In the embodiment including the third vacuum tank, the shape of the surface of the opening portion adjacent to the communication surface may be determined on the basis of the angular velocity at which the substrate is rotated in the second space.

As long as the substrate is rotated and the substrate is of significant dimensions, the rotational speed of the substrate in the second space varies according to the position of the substrate, more specifically, the distance from the axis defining the rotation center. In particular, when the center of the communication surface between the second space and the third space does not intersect with the axis defining the rotational center of the holder, the radius at which the holder is rotated is relatively large, and thus the effect of the variation is significant. That is, the velocity (i.e., the angular velocity) at which the substrate passes over the communication surface is different between the inner peripheral side (the side adjacent to the central axis of rotation of the holder) and the outer peripheral side (the side distant from the central axis).

Therefore, when the shape of the surface of the opening portion adjacent to the communication surface is not different between the inner peripheral side and the outer peripheral side, the film thickness in the outer peripheral side at which the passing velocity is relatively high tends to be smaller than that in the inner peripheral side. Accordingly, when the shape of the surface of the opening portion adjacent to the communication surface is determined on the basis of the angular velocity at which the substrate is rotated in the second space, such a problem is eliminated and, mainly, the predetermined film thickness can be preferably easily obtained.

In this embodiment, the shape of the surface of the opening portion adjacent to the communication surface may be determined so that the time required for depositing the evaporated substance on a unit area of the substrate is constant over the entire area of the substrate.

When the angular velocity is different between positions of the substrate as described above, typically, the time required for depositing the evaporated substance on a unit area of the substrate tends to be longer at the inner peripheral side of the rotation and tends to be shorter at the outer peripheral side thereof. Accordingly, when the shape of the surface adjacent to the communication surface is determined so that the above time is constant over the entire area of the substrate, an unevenness of evaporation due to the difference in the angular velocity can be suitably eliminated.

In the embodiment in which the restrictor includes the shielding portion and the opening portion, the surface of the opening portion adjacent to the communication surface may have a shape that gradually diverges from an axis defining the rotation center of the holder.

This structure can effectively cancel out the difference in the angular velocity between the inner periphery and the outer periphery on the substrate passing over the communication surface. In this case, the line segment joining an arc (or a point) at the inner peripheral side and an arc at the outer peripheral side may be a straight line or a curved line.

When the evaporation source is sufficiently small to be considered as a point evaporation source, the substance from the evaporation source isotropically evaporates radially from the evaporation source. Therefore, an ideal surface on which the evaporated substance is deposited with a uniform film thickness (i.e., a surface with a uniform film thickness) is a spherical surface at whose center is the evaporation source. On the other hand, when the evaporation source is not considered as a point evaporation source, for example, when the evaporation source is considered as having a small finite area, a surface with a uniform film thickness of the evaporated substance has a shape following the cosine law and is a virtual spherical surface formed above the evaporation source. In this case, when the shape of the surface of the opening portion is determined only on the basis of the angular velocity, the film thickness at the outer peripheral part of the substrate tends to be small. In preparation for this phenomenon, the surface of the opening portion may have a shape in which the opening portion diverges in a curved manner from the inner peripheral side to the outer peripheral side.

In this embodiment, the opening portion may have a three-dimensional shape in which the surface adjacent to the communication surface extends in the direction orthogonal to the communication surface.

In this case, since the opening portion has a three-dimensional shape, the evaporated substance is three-dimensionally restricted. That is, the opening portion has a function of a collimator. Therefore, such an opening portion is effective for forming an oblique film in an electro-optical device such as a liquid crystal device.

When the opening portion has a three-dimensional shape, there are two surfaces adjacent to the communication surface, i.e., the upper surface and the lower surface. These two surfaces do not necessarily have the same shape. For example, among the two surfaces adjacent to the communication surface, one surface facing the communication surface may have a shape of the opening portion larger than that of the other surface.

Alternatively, in the embodiment in which the restrictor includes the shielding portion and the opening portion, the opening portion may have a three-dimensional shape in which the surface adjacent to the communication surface has a rectangular shape and the rectangular surface extends in the direction orthogonal to the communication surface.

In the case where the surface adjacent to the communication surface has a rectangular shape, when the opening portion has a three-dimensional shape in which the rectangular surface extends in the direction orthogonal to the communication surface (i.e., in the direction parallel to the flight direction of the evaporated substance), as described above, a collimation function can be provided to the opening portion. In this case, the opening portion has, for example, a long slit shape.

In the embodiment in which the opening portion has a three-dimensional shape, the opening portion may extend so that the length thereof in the direction orthogonal to the communication surface gradually varies toward the central axis of the rotation of the holder.

In this case, a more effective collimation function can be provided to the opening portion. The length in the direction orthogonal to the communication surface may be determined on the basis of, for example, experimentation, experience, or simulation in advance so as to provide a desired collimation.

To solve the above problem, a method of producing an electro-optical device according to a third aspect includes forming an inorganic alignment layer for the electro-optical device on a substrate with the above vacuum evaporation apparatus in which an inorganic material is used as an evaporation source.

According to the method of producing an electro-optical device of the invention, in a process for producing an electro-optical device such as a liquid crystal display that can be used in various types of electronic equipment capable of displaying high-quality images, such as a projection display, a television, a cell phone, an electronic notebook, a word processor, viewfinder-type and direct-monitoring-type video tape recorders, a workstation, a picture telephone, a POS terminal, and a touch panel, an inorganic alignment layer can be evaporated with high productivity.

These operations and other benefits will be apparent from embodiments described below.

### BRIEF DESCRIPTION OF THE DRAWINGS

The invention will be described with reference to the accompanying drawings, wherein like numbers reference like elements.

FIG. 1 is a schematic perspective view of a vacuum evaporation apparatus according to a first embodiment of the invention.

FIG. 2 is schematic cross-sectional view of a side face of the vacuum evaporation apparatus shown in FIG. 1.

FIG. 3 is a schematic view of a shielding plate of the vacuum evaporation apparatus shown in FIG. 1.

FIG. 4 is a plan view of an opening portion shown in FIG. 3, viewed from above.

FIG. 5 is a plan view of a slit portion according a first modification of the invention.

FIG. 6 is a schematic perspective view of a shield according to a second embodiment of the invention.

FIGS. 7A to 7B are schematic perspective views of various slit portions according a second modification of the invention.

FIG. 8 relates to an embodiment of a method of producing an electro-optical device and is a process chart showing a flow of the production of a liquid crystal device.

### DESCRIPTION OF EXEMPLARY EMBODIMENTS

### Embodiments

Preferred embodiments will now be described with reference to the accompanying drawings accordingly.

### First Embodiment

Structure of the Embodiment

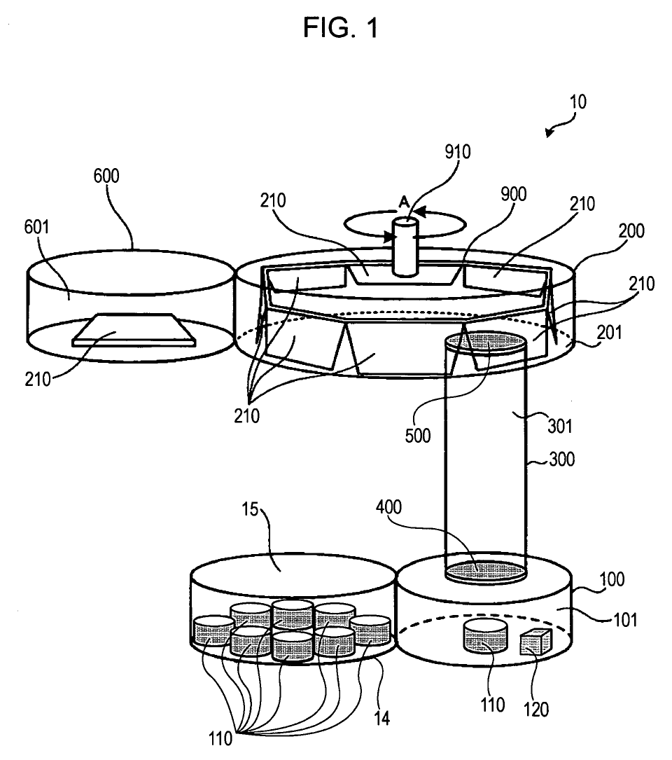

First, the structure of a vacuum evaporation apparatus 10 of a first embodiment will now be described with reference to FIG. 1. FIG. 1 is a schematic perspective view of the vacuum evaporation apparatus 10.

In FIG. 1, the vacuum evaporation apparatus 10 includes a target chamber 100, a process chamber 200, and a flight chamber 300.

The target chamber 100 is a vacuum tank, at least a part of which is composed of a metal such as aluminum or a steel such a stainless steel.

The inner wall of the target chamber 100 defines a space 101 inside the target chamber 100. A target 110 and an electron beam irradiation system 120 are disposed in the space 101. A part of the bottom surface of the target chamber 100 is connected to a first evacuation system 11 described below. The vacuum state in the space 101 can be maintained by discharging a gas in the space 101 to outside the target chamber 100. The first evacuation system 11 is a vacuum evacuation system including a rotary pump, which is a sub-evacuation unit (for example, used for roughing evacuation) and a turbomolecular pump, which is a main evacuation unit (for example, used for main evacuation).

The target 110 is, for example, a bulk inorganic material, which is a material for forming an inorganic alignment layer in an electro-optical device such as a liquid crystal device. The target 110 is disposed in a crucible (not shown in the figure).

The electron beam irradiation system 120 includes a filament, a part of a power supply system, a cooling water system, a control system, wiring components, and the like (not shown). An electron beam can be generated from the filament.

The target chamber 100 is connected to a target-supplying chamber 14 storing a plurality of unused targets 110. An inner space 15 of the target-supplying chamber 14 can be maintained in a vacuum state by means of an evacuation system (not shown). When the residual quantity of the target 110 is decreased in the target chamber 100, a valve (not shown) is opened and the target 110 is automatically exchanged or refilled while the vacuum state is maintained.

The flight chamber 300 is a tubular vacuum tank, at least a part of which is composed of a metal or a steel like the target chamber 100. The flight chamber 300 is disposed directly above the target 110 disposed in the target chamber 100. The inner wall of the flight chamber 300 defines a space 301 inside the flight chamber 300.

A part of the side face of the flight chamber 300 is connected to a third evacuation system 13 described below. The vacuum state in the space 301 can be maintained by discharging a gas in the space 301 to outside the flight chamber 300. The third evacuation system 13 is a vacuum evacuation system including a rotary pump, which is a sub-evacuation unit (for example, used for roughing evacuation) and a turbomolecular pump, which is a main evacuation unit (for example, used for main evacuation).

A gate valve 400 provided between the flight chamber 300 and the target chamber 100 controls the communicating state between the space 301 in the flight chamber 300 and the space 101 in the target chamber 100. The gate valve 400 will be described below.

The process chamber 200 is a vacuum tank, at least a part of which is composed of a metal or a steel like the target chamber 100 and the flight chamber 300. The inner wall of the process chamber 200 defines a space 201 inside the process chamber 200. A plurality of substrates 210 are disposed in the space 201. The substrates 210 are low-temperature polysilicon substrates that can be suitably used for an electro-optical device such as a liquid crystal device.

Each of the substrates 210 is held with a fixture 900 in the space 201 so as to be obliquely disposed at a predetermined angle relative to the internal surface of the process chamber 200. In the space 201, the fixture 900 is fixed to a shaft 910, a part of which is exposed outside the process chamber 200 while the hermeticity with the space 201 is maintained. As the shaft 910 is rotated in the A direction in the figure, the fixture 900 can also be rotated in the A direction in the figure.

A part of the side face of the process chamber 200 is connected to a second evacuation system 12 described below. The vacuum state in the space 201 can be maintained by discharging a gas in the space 201 to outside the process chamber 200. The second evacuation system 12 is a vacuum evacuation system including a rotary pump, which is a sub-evacuation unit (for example, used for roughing evacuation) and a turbomolecular pump, which is a main evacuation unit (for example, used for main evacuation).

A gate valve 500 provided between the process chamber 200 and the flight chamber 300 controls the communicating state between the space 201 in the process chamber 200 and the space 301 in the flight chamber 300. The gate valve 500 will be described below.

A load-lock chamber 600 is connected to the process chamber 200. The load-lock chamber 600 is a vacuum tank accommodating a plurality of substrates 210 in a space 601 defined by the inner wall thereof.

A valve (not shown) controls the communicating state between the load-lock chamber 600 and the process chamber 200. When the substrate 210 is supplied to the space 201, the valve is opened and the substrate 210 is automatically provided in the space 201 by a transfer system (not shown). The load-lock chamber 600 is connected to an evacuation system (not shown). While the evaporation process is performed in the process chamber 200 (that is, while the valve is closed), a gas that is present in the space 601 can be actively evacuated by the evacuation system. By the operation of this evacuation system, the substrates 210 can be transferred between the load-lock chamber 600 and the process chamber 200 while the vacuum state of the load-lock chamber 600 is maintained.

When the evaporation (i.e., film deposition) in the process chamber 200 is completed, the substrate 210 after deposition is discharged to a transfer chamber (not shown) that is connected to the process chamber 200 while the hermeticity is maintained.

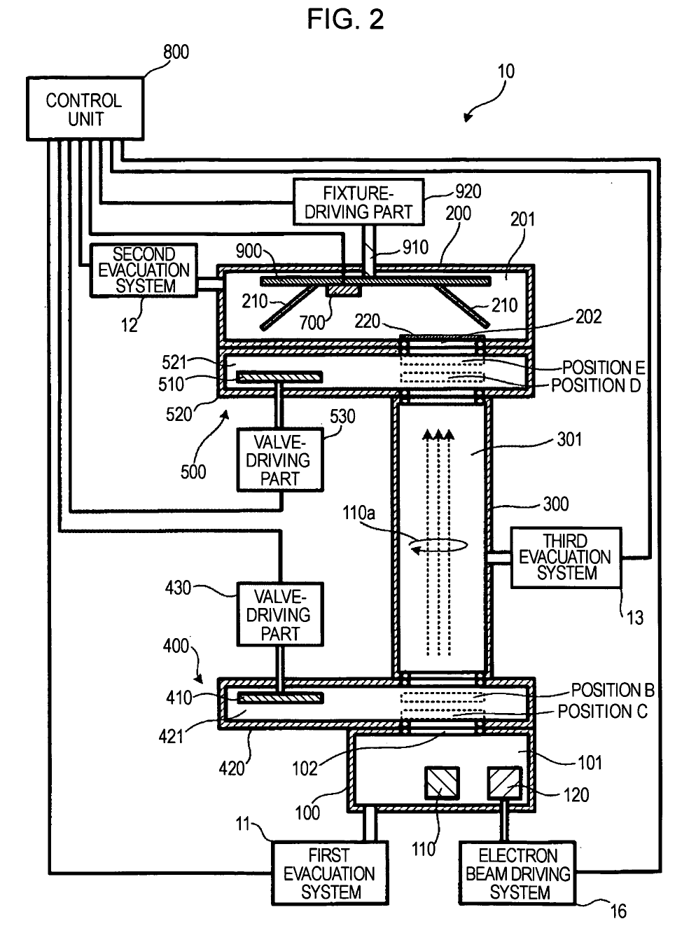

Next, the detailed structure of the vacuum evaporation apparatus 10 will be described with reference to FIG. 2. FIG. 2 is schematic cross-sectional view of a side face of the vacuum evaporation apparatus 10. In the figure, the same components as those in FIG. 1 have the same reference numerals and the description thereof is omitted. Additionally, in FIG. 2, the relative positional relationship of the target chamber 100, the process chamber 200, and the flight chamber 300 does not exactly correspond to that of real chambers in order to prevent a complex description.

In FIG. 2, the vacuum evaporation apparatus 10 includes a control unit 800. The control unit 800 controls the overall operation of the vacuum evaporation apparatus 10 and includes a central processing unit (CPU), a read only memory (ROM), a random access memory (RAM), and the like (not shown). The control unit 800 can control the operation of the vacuum evaporation apparatus 10 in response to the input operation from a touch panel unit, a keyboard, or an operation panel (not shown) provided in the vacuum evaporation apparatus 10, or according to a program stored in the ROM or the like in advance or a program supplied from the outside.

The gate valve 400 is provided between the target chamber 100 and the flight chamber 300. The gate valve 400 includes a valve part 410, a flange part 420, and a valve-driving part 430.

The valve part 410 is a disc-shaped metal component. The flange part 420 specifies the shape of the gate valve 400 and functions as a flange connecting the target chamber 100 and the flight chamber 300. A retreat space 421 for enabling retreat of the valve part 410 is provided inside the flange part 420. The valve-driving part 430 drives the valve part 410. The valve-driving part 430 is a system for electrically or mechanically driving the valve part 410. A part of the valve-driving part 430 is exposed outside the flange part 420 while the hermeticity is maintained. By means of an electrical or a mechanical control performed by the valve-driving part 430, the valve part 410 can be moved from the retreat space 421 to a space disposed directly on a communication opening 102 provided on the target chamber 100. Furthermore, in the space disposed directly on the communication opening 102, the valve part 410 can be moved in the vertical direction from a position B to a position C in the figure. When the position of the valve part 410 is controlled at the position C in the figure, the valve part 410 can separate the space 101 of the target chamber 100 from the space 301 of the flight chamber 300 while the hermeticity of each chamber is maintained. The valve-driving part 430 is electrically connected to the control unit 800. Thereby, the control unit 800 serves as a host controller of the valve-driving part 430. The valve-driving part 430 drives the valve part 410 in response to a control signal supplied from the control unit 800.

The gate valve 500 is provided between the process chamber 200 and the flight chamber 300. The gate valve 500 includes a valve part 510, a flange part 520, and a valve-driving part 530.

The valve part 510 is a disc-shaped metal component. The flange part 520 specifies the shape of the gate valve 500 and functions as a flange connecting the process chamber 200 and the flight chamber 300. A retreat space 521 for enabling retreat of the valve part 510 is provided inside the flange part 520. The valve-driving part 530 drives the valve part 510. The valve-driving part 530 is a system for electrically or mechanically driving the valve part 510. A part of the valve-driving part 530 is exposed outside the flange part 520 while the hermeticity is maintained. By means of an electrical or a mechanical control performed by the valve-driving part 530, the valve part 510 can be moved from the retreat space 521 to a space disposed directly under a communication opening 202 provided on the process chamber 200. Furthermore, in the space disposed directly under the communication opening 202, the valve part 510 can be moved in the vertical direction from a position D to a position E in the figure. When the position of the valve part 510 is controlled at the position E in the figure, the valve part 510 can separate the space 201 of the process chamber 200 from the space 301 of the flight chamber 300 while the hermeticity of each chamber is maintained. The valve-driving part 530 is electrically connected to the control unit 800. Thereby, the control unit 800 serves as a host controller of the valve-driving part 530. The valve-driving part 530 drives the valve part 510 in response to a control signal supplied from the control unit 800.

The control unit 800 controls the operations of the first evacuation system 11, the second evacuation system 12, and the third evacuation system 13. In this case, control signals directing the on/off state of the power supply of each vacuum pump provided in each evacuation system and the opening and closing of the solenoid valves provided therein are supplied to each evacuation system, thereby controlling the evacuation system. In addition, the control unit 800 can receive a sensor signal representing the degree of vacuum of each chamber from a vacuum gauge such as an ionization vacuum gauge provided in each evacuation system.

An electron beam driving system 16 controls the operation of the electron beam irradiation system 120. The electron beam driving system 16 includes a part of the power supply system and the cooling water system (not shown) that are not included in the electron beam irradiation system 120. The control unit 800 controls the operation of the electron beam driving system 16. The electron beam driving system 16 drives the electron beam irradiation system 120 in response to control signals directing the electrical conduction to the filament, the opening and closing of a cooling water valve, and the like, which are supplied from the control unit 800.

As described above, the fixture 900 holding the substrates 210 in the space 201 in the process chamber 200 is rotationally driven by the shaft 910. Furthermore, the shaft 910 is electrically or mechanically connected to a fixture-driving part 920 so that the rotational operation of the shaft 910 is controlled. The fixture-driving part 920 includes a power supply, an actuator, and the like. The motive power of the actuator operated by mean of electric power supplied from the power supply is converted to the rotational motive power of the shaft 910. Thus, eventually, the fixture 900 is rotationally driven. The control unit 800 serves as a host controller of the operation of the fixture-driving part 920. The fixture-driving part 920 drives the shaft 910 in response to a control signal supplied from the control unit 800.

A film thickness meter 700 is provided on a part in the space 201 of the process chamber 200, the part not facing the target 110. The film thickness meter 700 is a non contact-type film thickness meter using infrared rays. The film thickness meter 700 is electrically connected to the control unit 800 and an output signal of the film thickness meter 700 is output to the control unit 800.

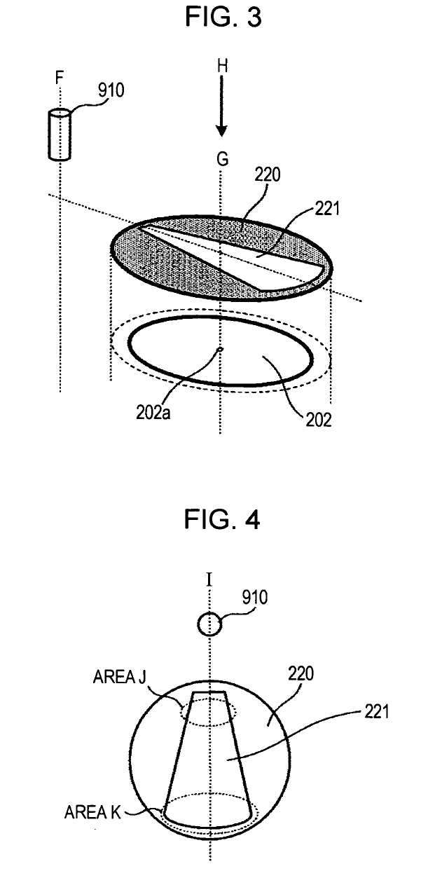

A shielding plate 220 is provided in the process chamber 200 so as to cover the communication opening 202. The shielding plate 220 will now be described in detail with reference to FIG. 3. FIG. 3 is a schematic view of the shielding plate 220. In the figure, components overlapping with those in FIG. 2 have the same reference numerals and the description thereof is omitted. Since the communication opening 202 is an opening portion provided in the process chamber 200, the communication opening 202 has a certain thickness. In this embodiment, however, the communication opening 202 is treated as a two-dimensional part whose thickness is negligible.

In FIG. 3, the shielding plate 220 is a thin disc-shaped metal component having a diameter larger than that of the communication opening 202. The shielding plate 220 includes a slit portion 221 that has a substantially wedge shape and that is formed by opening the surface adjacent to the communication opening 202. The space 201 of the process chamber 200 and the space 301 of the flight chamber 300 communicate with each other through the slit portion 221.

Since the flight space 301 (not shown in FIG. 3) is a cylindrical space, the communication opening 202 is also opened so as to have a round shape. An axis G passing through the center 202a of the communication opening 202 is parallel to an axis F passing through the shaft 910, the axis F defining the center when the fixture 900 is rotated. Accordingly, the axis G and the axis F do not intersect with each other. Thus, the space 301 communicates with the space 201 (not shown in FIG. 3) at a position shifted from the center of the bottom part of the process chamber 200 (not shown in FIG. 3).

The shielding plate 220 will now be described in more detail with reference to FIG. 4. FIG. 4 is a plan view of the slit portion 221 shown in FIG. 3, viewed from the direction shown by the arrow H. In the figure, the same components as those in FIG. 3 have the same reference numerals and the description thereof is omitted.

In FIG. 4, the slit portion 221 has a fan shape gradually converging in the direction of the shaft 910. That is, the slit portion 221 has a fan shape gradually diverging from the shaft 910. Accordingly, in the slit portion 221, the opening area in an area K is larger than that in an area J in the figure. The slit portion 221 is symmetric with respect to an extension line I joining the central line of the slit portion 221 and the shaft 910 in plan view.

Operation of the Embodiment

The operation of the vacuum evaporation apparatus 10 will now be described with reference to FIGS. 1 and 2 accordingly.

First, each of the evacuation systems 11, 12, and 13 is controlled by the control unit 800 so that each of the spaces 101, 201, and 301 reaches a predetermined degree of vacuum. On the other hand, the control unit 800 monitors the output signal from the ionization vacuum gauge provided in each evacuation system at a predetermined timing. Thus, the control unit 800 can make a decision whether each of the spaces has reached the predetermined degree of vacuum as a result of the evacuation operation of each evacuation system. In the same manner, each of the space 601 in the load-lock chamber 600 and the space 15 in the target-supplying chamber 14 is also evacuated by the evacuation system connected thereto so as to reach a predetermined degree of vacuum. In this case, each of the valve-driving parts is controlled so that the position of the valve part 410 of the gate valve 400 is controlled to the position C in the figure and the position of the valve part 510 of the gate valve 500 is controlled to the position E in the figure. That is, the space in each chamber is separately evacuated.

When each space reaches the predetermined degree of vacuum, the control unit 800 stores each of the valve parts of the gate valves in the corresponding retreating space in the flange part so as to enable the spaces 101, 201, and 301 to communicate with each other. In this step, the set degrees of vacuum in the spaces in the chambers are the same, and when the gate valves are controlled to be open, the variation in the degree of vacuum is small and negligible.

On the other hand, when the gate valves are controlled to be open, the control unit 800 opens a valve provided at a part communicating the space 601 in the load-lock chamber 600 with the space 201 in the process chamber 200 to supply the process chamber 200 with a predetermined number of the substrates 210 stored in the load-lock chamber 600. The control unit 800 controls the fixture-driving part 920 to allow the substrates 210 supplied from the load-lock chamber 600 to be held by the fixture 900.

When the predetermined number of substrates 210 are held by the fixture 900, the control unit 800 closes the valve provided between the load-lock chamber 600 and the process chamber 200, rotates the fixture 900 by means of the shaft 910 via the fixture-driving part 920, and starts the evaporation process.

In the evaporation process, the control unit 800 controls the electron beam driving system 16 to allow an electron beam to be irradiated from the electron beam irradiation system 120, thereby the target 110 is irradiated with the electron beam. The target 110 irradiated with the electron beam is heated and part of the target 110 is evaporated. An evaporated substance 110a composed of the evaporated target 110 flows into the space 301 from the space 101 through the communication opening 102, flies through the space 301, reaches the space 201 through the communication opening 202 and the above-described slit portion 221 provided in the shielding plate 220, and is eventually deposited on the substrate 210 that obliquely faces the target 110 at a position directly above the communication opening 202 and the shielding plate 220. As described above, the substrates 210 are rotatably held by the fixture 900 and pass over the communication opening 202 during the turning process. Accordingly, the term “substrate that obliquely faces the target 110” mainly represents a substrate passing over the communication opening 202. The evaporated substance 110a is deposited on the substrate 210 while the substrate 210 mainly passes over the communication opening 202.

The electron beam intensity (or filament current value) in the electron beam irradiation system 120, the rotational speed of the fixture 900, the process time (for example, the time required for completing the evaporation of all the substrates disposed in the space 201), and the like are set to the optimum values obtained by, for example, experimentation, experience, or simulation in advance. Basically, the control unit 800 cooperatively controls each part of the vacuum evaporation apparatus 10 according to such given process conditions. Furthermore, the control unit 800 monitors the output of the film thickness meter 700 at every moment while the evaporation process is performed. The control unit 800 appropriately performs the automatic stop of the evaporation process or a predetermined notification (such as an alarm) on the basis of the thickness of the deposited film obtained via the film thickness meter 700. Thus, the control unit 800 also contributes to the improvement in productivity by maintaining the quality level. Furthermore, the control unit 800 controls the operation of supplying (or exchanging) the target 110 from the target-supplying chamber 14 described above. In this case, each time a predetermined timing for supplying (or exchanging) the target occurs, the target 110 is automatically supplied (or exchanged) while the hermeticity between the space 15 of the target-supplying chamber 14 and the space 101 of the target chamber 100 is maintained. Accordingly, the target 110 is always used efficiently, which contributes to the improvement in productivity.

In this embodiment, the target 110 is composed of an inorganic material and an inorganic alignment layer is deposited on the substrates 210. During deposition, since the substrates 210 are obliquely disposed relative to the inner wall of the process chamber 200, the inorganic alignment layer composed of a large number of columnar structures that are obliquely aligned in the evaporation direction is satisfactorily formed from the evaporated substance 110a on the surface of the substrates 210. That is, the vacuum evaporation apparatus 10 has a structure in which an oblique evaporation of the inorganic material, i.e., the target 110, can be performed. Such an inorganic alignment layer can be suitably used as an alignment layer in a liquid crystal display device. In this case, a desired alignment layer (or a desired alignment direction or a pretilt angle) can be obtained by controlling the tilt direction, the tilt angle, and the like of the columnar structures. Thereby, the aligned state of liquid crystal molecules can be controlled. In addition, according to this inorganic alignment layer, since a rubbing treatment, which is required for an organic alignment layer, is not necessary, the number of steps of the rubbing treatment and the like can be reduced. Furthermore, this inorganic alignment layer is advantageous in that a force by which the liquid crystal molecules are maintained in a predetermined aligned state is stronger than that of the organic alignment layer.

In the evaporation process, the quality of the deposited film formed on the substrates 210 is appropriately controlled by the shielding plate 220. As shown in FIG. 3, the communication surface between the space 201 and the space 301 is disposed at a position distant from the rotation center of the fixture 900 and the substrates 210 held by the fixture 900. Accordingly, the velocity, i.e., angular velocity, at which the substrate 210 passes over the communication opening 202 varies over the substrate 210 according to the distance from the axis F passing through the shaft 910.

The slit portion 221 in this embodiment is formed so as to correspond to the angular velocity of the substrate. That is, the slit portion 221 is formed so that the inner peripheral part with a lower angular velocity has a smaller opening area whereas the outer peripheral part with a higher angular velocity has a larger opening area. More specifically, the slit portion 221 is formed so that the time required for depositing the evaporated substance 110a on a unit area of the substrate 210 is constant over the entire area (area to be deposited) of the substrate 210. This structure can eliminate an uneven deposition on the substrate caused by the rotation of the substrate 210. That is, because of the effect of the slit portion 221, the evaporated substance 110a is deposited on the substrate 210 with a uniform thickness. Consequently, the yield in the evaporation process can be increased to improve productivity.

Modification

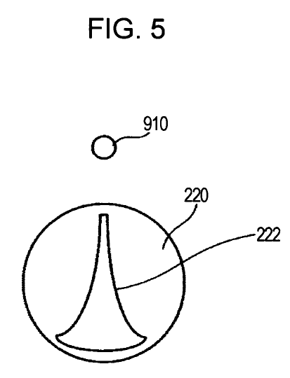

The slit portion provided in the shielding plate 220 is not limited to the above-described slit portion 221. For example, the slit portion 221 may have a shape shown in FIG. 5. FIG. 5 is a plan view of a slit portion 222 according a first modification of the invention. In the figure, the same components as those in FIG. 4 have the same reference numerals and the description thereof is omitted.

In FIG. 5, the slit portion 222 is the same as the above slit portion 221 in that the shape of the surface adjacent to the communication opening 202 is formed so that the outer peripheral part in the rotation of the substrate 210 has a larger opening area. However, the ratio of change in the opening area of the slit portion 222 is different from that of the slit portion 221. Specifically, among frame lines of the slit portion 222 defining the surface adjacent to the communication opening 202, frame lines in the radial direction intersecting the circumferential direction extend from the inner peripheral side to the outer peripheral side so as to form circular arc shapes. Thus, the opening area of the surface adjacent to the communication opening 202 is increased in a direction from the inner peripheral side to the outer peripheral side. According to this shape, the deviation of the distribution of the evaporated substance 110a due to, for example, the size and the shape of the target 110 disposed in the target chamber 100 can be appropriately corrected.

### Second Embodiment

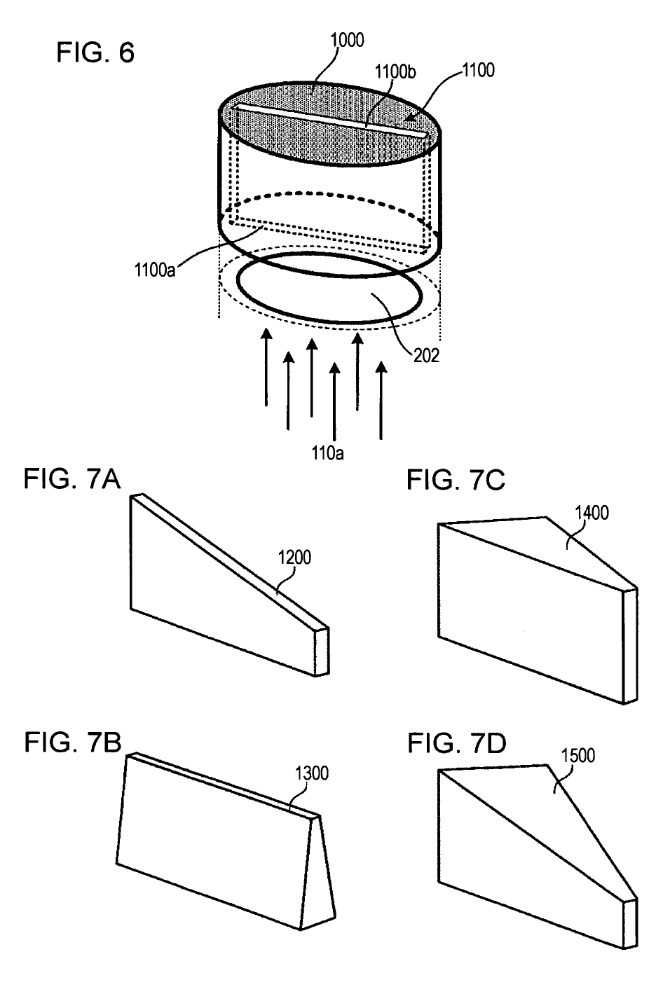

The form covering the communication opening 202 is not limited to the shielding plate 220 according to the first embodiment. Another example will be described with reference to FIG. 6. FIG. 6 is a schematic perspective view of a shield 1000 according to a second embodiment of the invention. In the figure, the same component as that in FIG. 3 has the same reference numeral and the description thereof is omitted.

In FIG. 6, the shield 1000 is a bulk component covering the communication opening 202 and includes a slit portion 1100 passing through the shield 1000.

The slit portion 1100 includes a rectangular lower opening area 1100a on a surface of the shield 1000 facing the communication opening 202 and an upper opening area 1100b on another surface of the shield 1000 facing the substrate 210, the upper opening area 1100b having the same shape as that of the lower opening area 1100a. The slit portion 1100 is a slit-shaped space passing through the shield 1000 from the lower opening area 1100a to the upper opening area 1100b.

According to the slit portion 1100, when the evaporated substance 110a passes through the slit portion 1100, the evaporated substance 110a collides with the inner wall of the shield 1000 that defines the slit portion 1100. As a result, the flight direction of the evaporated substance 110a finally passing through the upper opening area 1100b is relatively aligned. That is, the three-dimensional slit portion 1100 of this embodiment can provide the evaporated substance 110a with a preferred collimation.

As described above, in the vacuum evaporation apparatus 10, an inorganic alignment layer that can be suitably used in an electro-optical device such as a liquid crystal device can be formed by oblique evaporation. In the case where the collimation of the evaporated substance 110a is insufficient, even when the deposited film has a uniform thickness, the film cannot satisfactorily function as an alignment layer. According to this embodiment, the slit portion 1100 functions as a collimator for providing the evaporated substance 110a with collimation. Thus, preferably, the resulting deposited film can satisfactorily function as an alignment layer.

Modifications

The three-dimensional slit portion according to the second embodiment is not limited to the above-described slit portion 1100 and various forms can be used. A second modification will now be described with reference to FIGS. 7A to 7D. FIGS. 7A to 7B are schematic perspective views of various slit portions according the second modification of the invention. In the figure, the description of the same components as those in FIG. 6 is omitted.

In the figures, the three-dimensional slit portion provided in the shield 1000 (not shown) may be a slit portion 1200 (FIG. 7A) in which the length thereof in the flight direction (i.e., the direction intersecting with the communication opening 202) of the evaporated substance 110a of the above-described slit portion 1100 is continuously varied. Alternatively, the three-dimensional slit portion may be a slit portion 1300 (FIG. 7B) in which the lower opening area and the upper opening area each have a rectangular shape and the areas thereof are different from each other.

The shape of the lower opening area and the upper opening area is not limited to a rectangle. For example, the three-dimensional slit portion may be a slit portion 1400 (FIG. 7C) in which the lower opening area and the upper opening area each have a fan shape as in the slit portion 221 in the first embodiment. Alternatively, the three-dimensional slit portion may be a slit portion 1500 (FIG. 7D) in which the length in the flight direction of the evaporated substance 110a of the slit portion 1400 is continuously varied. These various shapes of the slit portion may be appropriately determined in advance on the basis of experimentation, experience, simulation, or the like according to the film properties required for the resulting deposited film. Method of producing an electro-optical device

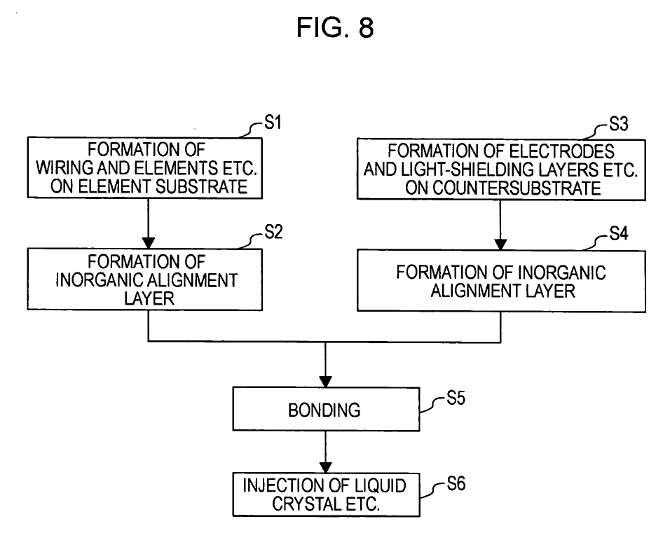

A method of producing an electro-optical device using the vacuum evaporation apparatus according to the above-described embodiment will now be described with reference to FIG. 8. Here, as an example of the electro-optical device, a process of producing a liquid crystal device in which a liquid crystal, which is an example of an electro-optic material, is interposed between a pair of substrates, i.e., an element substrate and a countersubstrate, will be described. FIG. 8 is a process chart showing a flow of the production of the liquid crystal device.

In FIG. 8, first, various types of wiring, electronic elements, electrodes, internal circuits, and the like are appropriately formed on an element substrate by a known thin-film forming technique, a patterning technique, and the like according to the model to be produced (Step S1). Subsequently, an inorganic alignment layer having a predetermined pretilt angle is formed on a surface of the element substrate that faces a countersubstrate by oblique evaporation using the vacuum evaporation apparatus 10 of the above embodiment (Step S2).

On the other hand, various electrodes, light-shielding films, color filters, microlenses, and the like are appropriately formed on the countersubstrate by a known thin-film forming technique, a patterning technique, and the like according to the model to be produced (Step S3). Subsequently, an inorganic alignment layer having a predetermined pretilt angle is formed on a surface of the countersubstrate that faces the element substrate by oblique evaporation using the vacuum evaporation apparatus 10 of the above embodiment (Step S4).

The pair of the element substrate and the countersubstrate each having the inorganic alignment layer are then bonded so that the inorganic alignment layers face each other with a sealing material such as a UV curable resin, a thermosetting resin, or the like (Step S5). Subsequently, a liquid crystal is injected between the bonded substrates by vacuum suction or the like. For example, sealing with a sealant such as an adhesive, washing, and inspection are then performed (Step S6).

Thus, the production of the liquid crystal device including the inorganic alignment layers formed by oblique evaporation using the vacuum evaporation apparatus 10 of the above embodiment is completed. Since the inorganic alignment layers are formed using the vacuum evaporation apparatus 10 of the above embodiment, according to this production method, the production efficiency including the time required for maintenance can be significantly increased.

The invention is not limited to the above embodiments and can be appropriately modified within the range that does not depart from the scope and spirit of the invention that can be read from the claims and the specification. A vacuum evaporation apparatus and a method of producing an electro-optical device that include such modifications are also included in the technical scope of the invention.

The entire disclosure of Japanese Patent Application Nos. 2005-195463, filed Jul. 4, 2005, and 2006-009610, filed Jan. 18, 2006, are expressly incorporated by reference herein.

What is claimed is:

1. A vacuum evaporation apparatus comprising:
a first vacuum tank that defines a first space and that can maintain a vacuum state in the first space;
an electron beam irradiator that irradiates an electron beam on an evaporation source in the first space to evaporate part of the evaporation source into an evaporated substance;
a second vacuum tank that defines a second space that can be brought selectively into and out of communication with the second space, the second vacuum tank maintaining a vacuum state in the second space while the first and second spaces are in communication;
a holder that holds a substrate in the second space so that at least part of the substrate faces at least part of the evaporation source in the second space;
a rotator that rotates the holder so that the held substrate is rotated in the second space in a direction substantially orthogonal to the flight direction of the evaporated substance from the first space; and
a restrictor that is provided between the evaporation source and the substrate and that restricts the access of the evaporated substance on the substrate, the restrictor restricting access of the evaporated substance on the substrate so that the film properties of the deposited film are closer to predetermined properties than if access were not restricted.

2. The vacuum evaporation apparatus according to claim 1, further comprising:
a third vacuum tank that is provided between the first vacuum tank and the second vacuum tank so as to be removable from each of the first vacuum tank and the second vacuum tank, that defines a third space (i) capable of communicating with the first space and the second space and (ii) functioning as a space through which the evaporated substance is made to fly to the second space in a state in which the third vacuum tank is connected to the first vacuum tank and the second vacuum tank, and that can maintain a vacuum state of the third space in a state in which at least the third space communicates with the first space and the second space.

3. The vacuum evaporation apparatus according to claim 1, wherein the holder holds the substrate so that at least part of the substrate obliquely faces the evaporated substance made to fly from the first space.

4. The vacuum evaporation apparatus according to claim 1,
wherein the film properties include the thickness of the deposited film, and
the restrictor restricts the access of the evaporated substance on the substrate so that the thickness is within a predetermined range.

5. The vacuum evaporation apparatus according to claim 1,
wherein the film properties include the aligned state of the deposited film, and
the restrictor restricts the access of the evaporated substance on the substrate so that the aligned state becomes close to being uniform compared with the case where the access on the substrate is not restricted.

6. The vacuum evaporation apparatus according to claim 2, wherein the second vacuum tank is provided so that the center of a communication surface between the second space and the third space does not intersect with an axis defining the rotation center of the holder.

7. The vacuum evaporation apparatus according to claim 2, wherein the restrictor includes
a shielding portion covering at least a part of a communication surface between the second space and the third space, and
an opening portion provided in a part of the shielding portion.

8. The vacuum evaporation apparatus according to claim 7, wherein the shape of the surface of the opening portion adjacent to the communication surface is determined on the basis of the angular velocity at which the substrate is rotated in the second space.

9. The vacuum evaporation apparatus according to claim 8, wherein the shape of the surface of the opening portion adjacent to the communication surface is determined so that the time required for depositing the evaporated substance on a unit area of the substrate is constant over the entire area of the substrate.

10. The vacuum evaporation apparatus according to claim 7, wherein the surface of the opening portion adjacent to the communication surface has a shape that gradually diverges from an axis defining the rotation center of the holder.

11. The vacuum evaporation apparatus according to claim 10, wherein the opening portion has a three-dimensional shape in which the surface adjacent to the communication surface extends in the direction orthogonal to the communication surface.

12. The vacuum evaporation apparatus according to claim 7, wherein the opening portion has a three-dimensional shape in which the surface adjacent to the communication surface has a rectangular shape and the rectangular surface extends in the direction orthogonal to the communication surface.

13. The vacuum evaporation apparatus according to claim 11, wherein the opening portion extends so that the length thereof in the direction orthogonal to the communication surface gradually varies toward the central axis of the rotation of the holder.

14. A vacuum evaporation apparatus comprising:
a first vacuum tank that defines a first space and that can maintain a vacuum state in the first space;
an electron beam irradiator that irradiates an electron beam on an evaporation source in the first space to evaporate part of the evaporation source into an evaporated substance;
a second vacuum tank that defines a second space that can be brought selectively into and out of communication with the second space, the second vacuum tank maintaining a vacuum state in the second space while the first and second spaces are in communication;
a holder that holds a substrate in the second space so that at least part of the substrate faces at least part of the evaporation source in the second space;
a rotator that rotates the holder so that the held substrate is rotated in the second space in a direction substantially orthogonal to the flight direction of the evaporated substance from the first space; and
a restrictor that is provided between the evaporation source and the substrate and that restricts the access of the evaporated substance on the substrate, the restrictor including a shielding portion covering at least a part of a communication surface between the second space and a third space and an opening portion provided in a part of the shielding portion, the opening portion adjacent to the communication surface has a shape gradually diverging from an imaginary axis at the rotation center of the holder.
